(19) United States
(12) Patent Application Publication
(10) Pub. No.: US 2026/0043123 A1
(43) Pub. Date: Feb. 12, 2026

(54) MASK ASSEMBLY AND DEPOSITION DEVICE INCLUDING THE SAME

(71) Applicant: Samsung Display Co., Ltd., Yongin-si (KR)

(72) Inventors: SEIL KIM, Yongin-si (KR); SEUNGJIN LEE, Yongin-si (KR); JAESUK MOON, Yongin-si (KR); HONGJOO JEON, Yongin-si (KR); MIN JU CHOI, Yongin-si (KR)

(21) Appl. No.: 19/226,569

(22) Filed: Jun. 3, 2025

(30) Foreign Application Priority Data
Aug. 9, 2024 (KR) 10-2024-0106574

(51) Int. Cl. C23C 14/04; H10K 59/12; H10K 59/122; H10K 71/16

(52) U.S. Cl. CPC C23C 14/042; H10K 59/1201; H10K 59/122; H10K 71/166

(57) ABSTRACT

A deposition device includes: a mask frame in which a frame opening is defined; and a mask stick disposed on the mask frame and extending longer in a second direction than extending in a first direction crossing the second direction. A plurality of openings arranged in the first direction and the second direction are defined in the mask stick. The mask stick includes: first branch portions between openings adjacent to each other in the first direction and a first edge portion between a first side of opposite sides of the mask stick opposite each other in the first direction and openings adjacent to the first side. In the first direction, a first width of the first edge portion is set in a range of 90% of a first branch width of each of the first branch portions to 110% of the first branch width.

This application claims priority to Korean Patent Application No. 10-2024-0106574 filed on Aug. 9, 2024, and all the benefits accruing therefrom under 35 U.S. C. § 119, the content of which in its entirety is herein incorporated by reference.

### BACKGROUND

Embodiments of the present disclosure described herein relate to a mask assembly.

In general, electronic devices, such as smart phones, digital cameras, notebook computers, car navigation units, smart televisions, and the like, which provide an image to a user include a display device for displaying an image. The display device generates an image and provides the generated image to the user through a display screen.

Among various display devices, an organic light emitting display device includes light emitting elements for generating light. Each of the light emitting elements includes an anode, an emissive layer, and a cathode. Holes and electrons are injected into the emissive layer from the anode and the cathode, respectively, to form excitons, and the light emitting element emits light as the excitons transition to a ground state.

A mask assembly is disposed over a substrate when the light emitting elements are manufactured. The mask assembly includes a mask frame that has a frame shape and in which a frame opening is defined and a plurality of mask sticks disposed on the mask frame. Openings are defined in the mask sticks, and an organic material for forming the emissive layers is provided on the substrate through the openings.

### SUMMARY

Embodiments of the present disclosure provide a mask assembly appropriate for manufacturing a high-resolution display device.

According to an embodiment, a deposition device includes: a mask frame in which a frame opening is defined; and a mask stick disposed on the mask frame and that extends longer in a second direction than extending in a first direction crossing the second direction. A plurality of openings arranged in the first direction and the second direction are defined in the mask stick. The mask stick includes: first branch portions between openings adjacent to each other in the first direction among the plurality of openings and a first edge portion between a first side of opposite sides of the mask stick opposite each other in the first direction and openings adjacent to the first side among the plurality of openings. In the first direction, a first width of the first edge portion is set in a range of 90% of a first branch width of each of the first branch portions to 110% of the first branch width.

According to an embodiment, a mask assembly includes: a mask frame in which a frame opening is defined; and a mask stick disposed on the mask frame and extending longer in a second direction than in a first direction crossing the second direction. A plurality of openings arranged in the first direction and the second direction are defined in the mask stick. The mask stick includes: first branch portions between openings adjacent to each other in the first direction among the plurality of openings, a first edge portion between a first side of opposite sides of the mask stick opposite each other in the first direction and openings adjacent to the first side among the plurality of openings, and a second edge portion between a second side of the opposite sides of the mask stick and openings adjacent to the second side among the plurality of openings. In the first direction, a first width of the first edge portion and a second width of the second edge portion each are set in a range of 90% of a first branch width of each of the first branch portions to 110% of the first branch width.

According to an embodiment, a mask assembly includes: a mask frame in which a frame opening is defined; and a plurality of mask sticks that are disposed on the mask frame and arranged in a first direction and each of which extends longer in a second direction than extends in a first direction crossing the second direction. A plurality of openings arranged in the first direction and the second direction are defined in each of the plurality of mask sticks. Each of the plurality of mask sticks includes: first branch portions between openings adjacent to each other in the first direction among the plurality of openings and a first edge portion between a first side of opposite sides of the mask stick opposite each other in the first direction and openings adjacent to the first side among the plurality of openings. In the first direction, a first width of the first edge portion is set in a range of 90% of a first branch width of each of the first branch portions to 110% of the first branch width. A gap between two mask sticks adjacent to each other in the first direction among the plurality of mask sticks is equal to a width of each of the plurality of openings in the first direction.

### BRIEF DESCRIPTION OF THE FIGURES

The above and other aspects and features of the present disclosure will become apparent by describing in detail embodiments thereof with reference to the accompanying drawings.

FIG. 1 is an exploded perspective view of a mask assembly according to an embodiment of the present disclosure.

FIG. 2 is a view illustrating a state in which mask sticks illustrated in FIG. 1 are coupled to a mask frame.

FIG. 3 is a plan view of the mask assembly when the mask assembly illustrated in FIG. 2 is viewed from above.

FIG. 4 is an enlarged plan view of portions of two mask sticks adjacent to each other among the mask sticks illustrated in FIG. 2.

FIG. 5 is a view illustrating a display device including light emitting elements formed using the mask assembly illustrated in FIGS. 1 to 3.

FIG. 6 is a sectional view of one pixel illustrated in FIG. 5.

FIG. 7 is a view illustrating light emitting elements disposed in a portion of a display area of a display panel illustrated in FIG. 5.

FIG. 8 is a sectional view illustrating a deposition device including the mask assembly illustrated in FIGS. 1 to 3.

FIG. 9 is a sectional view for explaining a process of forming an emissive layer using the deposition device illustrated in FIG. 8.

FIGS. 10A, 10B, and 10C are plan views for explaining a process of forming first, second, and third light emitting elements through mask sticks.

FIG. 11 is a view illustrating a configuration of mask sticks according to a comparative example.

FIG. 12 is a plan view illustrating a configuration of mask sticks according to an embodiment of the present disclosure.

FIGS. 13 and 14 are plan views illustrating a configuration of third mask sticks according to embodiments of the present disclosure.

FIG. 15 is a plan view illustrating an example in which a mask assembly according to an embodiment of the present disclosure is used for a small or medium-sized display panel.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

As used herein, the term “and/or” includes all of one or more combinations defined by related components.

Terms such as “first”, “second”, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

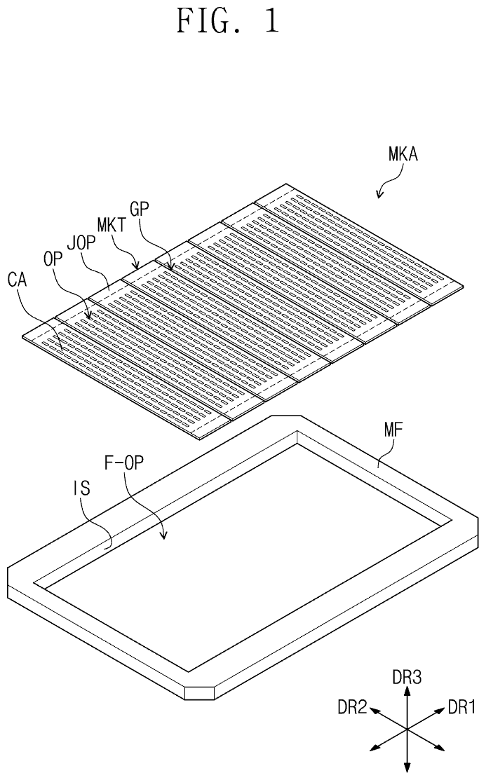

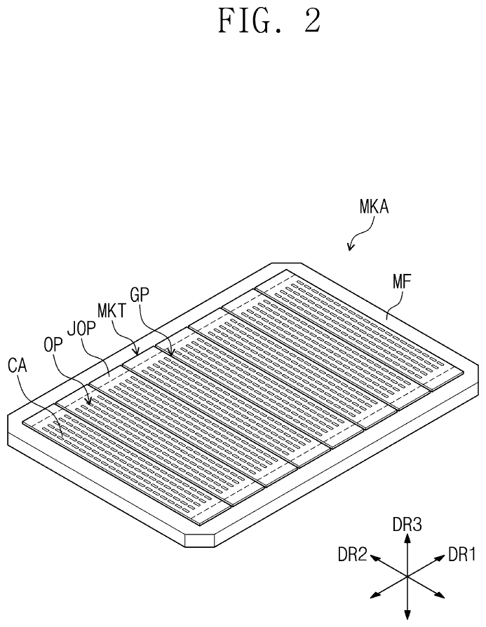

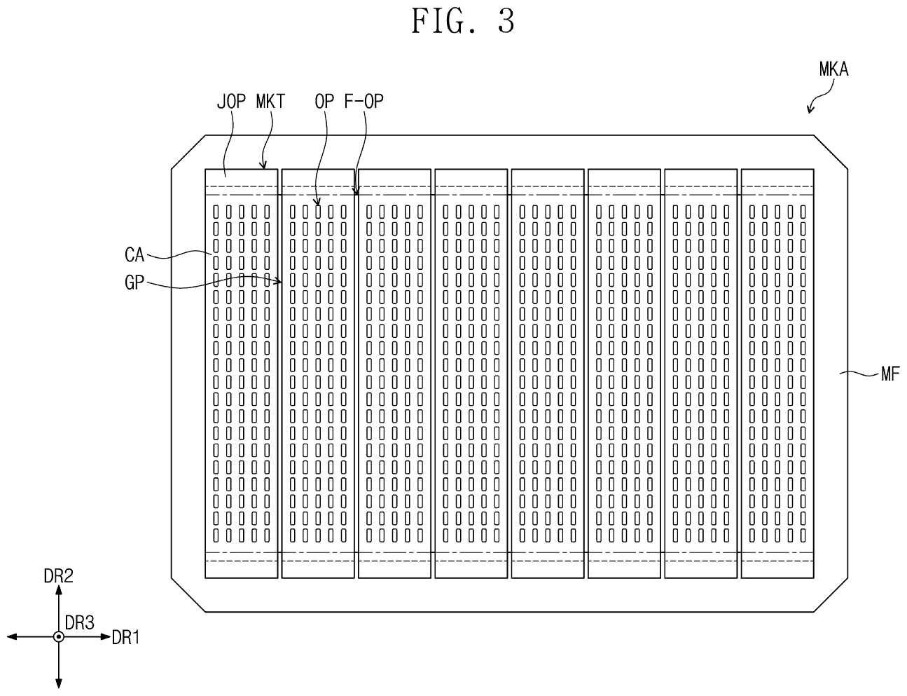

FIG. 1 is an exploded perspective view of a mask assembly according to an embodiment of the present disclosure. FIG. 2 is a view illustrating a state in which mask sticks illustrated in FIG. 1 are coupled to a mask frame. FIG. 3 is a plan view of the mask assembly when the mask assembly illustrated in FIG. 2 is viewed from above. As used herein, the “plan view” is a view in a thickness direction (i.e., third direction DR3) of the mask assembly MKA.

Referring to FIGS. 1, 2, and 3, the mask assembly MKA according to an embodiment of the present disclosure may include the mask frame MF and the plurality of mask sticks MKT.

The mask frame MF may have a frame shape. The mask frame MF may extend longer in a first direction DR1 than in a second direction DR2 crossing the first direction DR1. The first direction DR1 and the second direction DR2 may cross substantially perpendicular to each other.

Hereinafter, a direction crossing a plane defined by the first direction DR1 and the second direction DR2 is defined as a third direction DR3. The third direction DR3 may be substantially perpendicular to the plane defined by the first direction DR1 and the second direction DR2. The expression “when viewed from above the plane” used herein may mean that it is viewed in the third direction DR3 (i.e., plan view).

The mask frame MF may have a frame opening F-OP defined therein. The frame opening F-OP may be defined to penetrate the mask frame MF in the third direction DR3. The frame opening F-OP may have a rectangular shape when viewed from above the plane. The frame opening F-OP may have a rectangular shape extending longer in the first direction DR1 than in the second direction DR2.

The mask frame MF may include a metallic material. For example, the mask frame MF may include invar or stainless steel.

The mask sticks MKT may be disposed on the mask frame MF. The mask sticks MKT may be arranged in the first direction DR1. The mask sticks MKT may be spaced apart from one another by a predetermined gap GP in the first direction DR1. The mask sticks MKT may be spaced apart from one another by the same gap GP in the first direction DR1.

Each of the mask sticks MKT may have a rectangular shape extending longer in the second direction DR2 than in the first direction DR1. That is, each of the mask sticks MKT may have a rectangular shape with long sides extending in the second direction DR2 and short sides extending in the first direction DR1. Accordingly, the mask stick MKT may have a bar shape extending in the second direction DR2.

A plurality of openings OP may be defined in each of the mask sticks MKT. The openings OP may be arranged in the first direction DR1 and the second direction DR2. The openings OP may be defined to penetrate the mask sticks MKT in the third direction DR3. The openings OP may extend longer in the second direction DR2 than in the first direction DR1.

Each of the mask sticks MKT may include a cell area CA in which the openings OP are defined and coupling portions JOP adjacent to the cell area CA. The openings OP may not be defined in the coupling portions JOP. The openings OP defined in the mask sticks MKT may overlap the frame opening F-OP when viewed from above the plane. For example, in FIG. 3, the frame opening F-OP overlapping the mask sticks MKT is illustrated by a dash-dot-dash line.

Portions of each mask stick MKT that are adjacent to opposite sides of the mask stick MKT opposite each other in the second direction DR2 may be defined as the coupling portions JOP. Accordingly, in the mask stick MKT, the coupling portions JOP may be spaced apart from each other in the second direction DR2, and the cell area CA may be disposed between the coupling portions JOP.

The coupling portions JOP may overlap portions of the mask frame MF that are adjacent to inner surfaces IS facing each other in the second direction DR2 among inner surfaces IS of the mask frame MF that define the frame opening F-OP.

The coupling portions JOP may be coupled to the portions of the mask frame MF that are adjacent to the inner surfaces IS facing each other in the second direction DR2. For example, the coupling portions JOP may be coupled to the mask frame MF by a welding process. The coupling portions JOP of the mask sticks MKT may be coupled to the mask frame MF to overlap the mask frame MF in a plan view.

The mask sticks MKT may include a metallic material. For example, the mask sticks MKT may include invar or stainless steel. In an embodiment of the present disclosure, the mask sticks MKT may include invar.

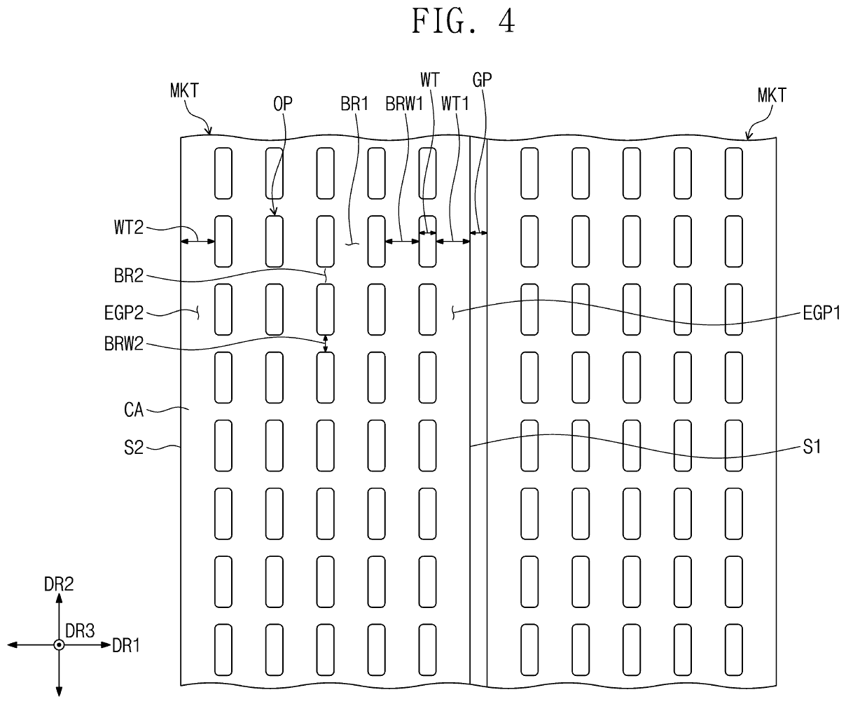

FIG. 4 is an enlarged plan view of portions of two mask sticks adjacent to each other among the mask sticks illustrated in FIG. 2.

For example, in FIG. 4, portions of the mask sticks MKT are illustrated in the second direction DR2, and opposite sides of the mask sticks MKT are illustrated in the first direction DR1.

Since the mask sticks MKT have substantially the same configuration, the configuration of one mask stick MKT will be described below.

Referring to FIG. 4, opposite sides of the mask stick MKT opposite each other in the first direction DR1 are defined as a first side S1 and a second side S2. The first side S1 and the second side S2 may extend parallel to each other in the second direction DR2.

The mask stick MKT may include a plurality of first branch portions BR1, a plurality of second branch portions BR2, a first edge portion EGP1, and a second edge portion EGP2. Substantially, the cell area CA may include the first branch portions BR1, the second branch portions BR2, the first edge portion EGP1, and the second edge portion EGP2.

Each of the first branch portions BR1 may be disposed between the openings OP adjacent to each other in the first direction DR1. That is, the first branch portion BR1 may be defined as a portion of the mask stick MKT disposed between the openings OP adjacent to each other in the first direction DR1. The first branch portion BR1 may be disposed between two openings OP adjacent to each other in the first direction DR1.

Each of the second branch portions BR2 may be disposed between the openings OP adjacent to each other in the second direction DR2. That is, the second branch portion BR2 may be defined as a portion of the mask stick MKT disposed between the openings OP adjacent to each other in the second direction DR2. The second branch portion BR2 may be disposed between two openings OP adjacent to each other in the second direction DR2.

The first edge portion EGP1 may be disposed between the first side S1 and the openings OP adjacent to the first side S1. That is, the first edge portion EGP1 may be defined as a portion of the mask stick MKT disposed between the first side S1 and the openings OP adjacent to the first side S1.

The second edge portion EGP2 may be disposed between the second side S2 and the openings OP adjacent to the second side S2. That is, the second edge portion EGP2 may be defined as a portion of the mask stick MKT disposed between the second side S2 and the openings OP adjacent to the second side S2.

The openings OP adjacent to the first side S1 and the openings OP adjacent to the second side S2 may indicate the outermost openings OP in the first direction DR1.

Each of the first branch portions BR1 may have a first branch width BRW1 in the first direction DR1. Each of the second branch portions BR2 may have a second branch width BRW2 in the second direction DR2. The second branch width BRW2 may be smaller than the first branch width BRW1.

The first edge portion EGP1 may have a first width WT1 in the first direction DR1. The second edge portion EGP2 may have a second width WT2 in the first direction DR1. The first width WT1 may be set in the range of 90% of the first branch width BRW1 to 110% of the first branch width BRW1. Preferably, the first width WT1 may be equal to the first branch width BRW1.

The second width WT2 may be equal to the first width WT1. Accordingly, the second width WT2 may be set in the range of 90% of the first branch width BRW1 to 110% of the first branch width BRW1. Preferably, the second width WT2 may be equal to the first branch width BRW1. Depending on this structure, each of the mask sticks MKT may have a symmetrical shape in the first direction DR1.

For example, the first width WT1 may be set in the range of 90% of the first branch width BRW1 to 110% of the first branch width BRW1 and may be set to 300 micrometers (μm) or less.

The gap GP between the two mask sticks MKT adjacent to each other in the first direction DR1 may be equal to the width WT of each of the openings OP in the first direction DR1.

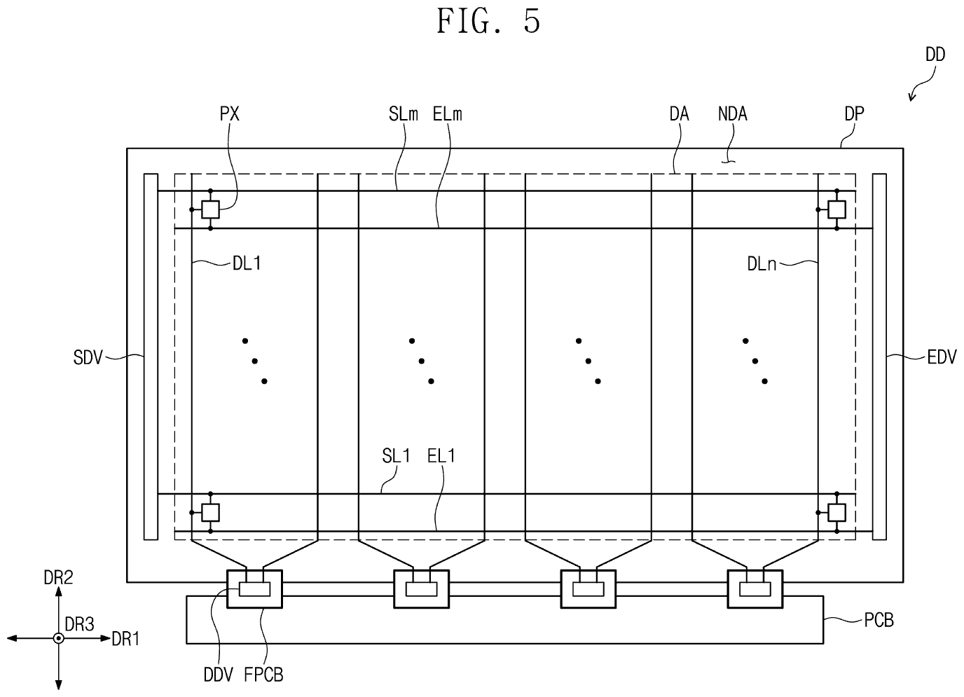

FIG. 5 is a view illustrating a display device including light emitting elements formed using the mask assembly illustrated in FIGS. 1 to 3.

Referring to FIG. 5, the display device DD may include a display panel DP, a scan driver SDV, a plurality of data drivers DDV, a plurality of flexible circuit boards FPCB, an emission driver EDV, and a printed circuit board PCB.

The display panel DP may include a display area DA and a non-display area NDA surrounding the display area DA. The display area DA may substantially correspond to the frame opening F-OP illustrated in FIG. 1.

The display panel DP may have a rectangular shape with long sides extending in the first direction DR1 and short sides extending in the second direction DR2. The display panel DP may include a plurality of pixels PX, a plurality of scan lines SL1 to SLm, a plurality of data lines DL1 to DLn, and a plurality of emission lines EL1 to ELm. “m” and “n” are natural numbers.

The pixels PX may be disposed in the display area DA. The pixels PX may include the light emitting elements formed using the mask assembly MKA illustrated in FIGS. 1 to 3. Substantially, emissive layers of the light emitting elements may be formed by the mask assembly MKA. The configuration of the light emitting elements will be described below in detail.

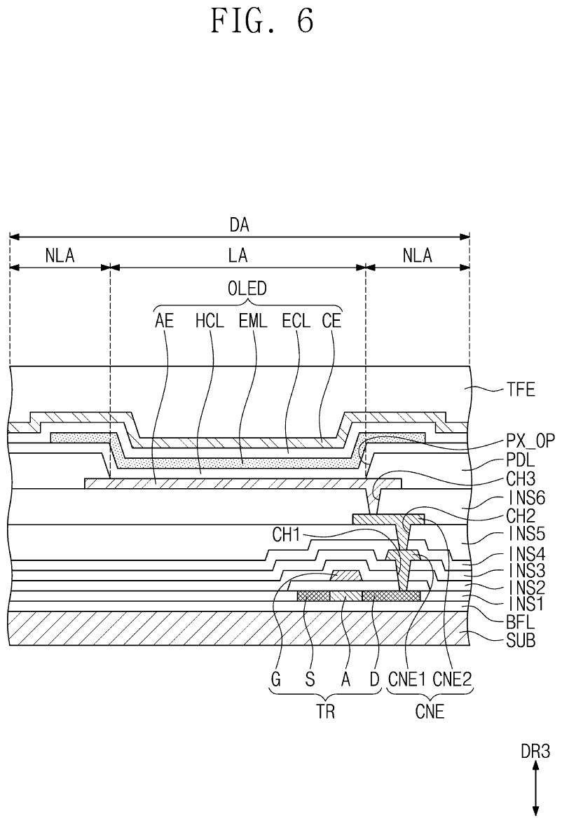

The scan driver SDV and the emission driver EDV may be disposed in the non-display areas NDA adjacent to the short sides of the display panel DP, respectively. The pixels PX may include the light emitting elements, respectively, and the configuration of the light emitting elements is illustrated in FIG. 6.

The data drivers DDV, when viewed from above the plane, may be disposed adjacent to the lower side of the display panel DP defined by one of the long sides of the display panel DP. The printed circuit board PCB, when viewed from above the plane, may be disposed adjacent to the lower side of the display panel DP.

The flexible circuit boards FPCB may be connected to the lower side of the display panel DP and the printed circuit board PCB. The data drivers DDV may be manufactured in the form of an integrated circuit chip and may be mounted on the respective flexible circuit boards FPCB. Although four flexible circuit boards FPCB and four data drivers DDV are illustrated as an example, the number of flexible circuit boards FPCB and the number of data drivers DDV are not limited thereto.

The scan lines SL1 to SLm may extend in the first direction DR1 and may be connected to the pixels PX and the scan driver SDV. The emission lines EL1 to ELm may extend in the first direction DR1 and may be connected to the pixels PX and the emission driver EDV.

The data lines DL1 to DLn may extend in the second direction DR2 and may be connected to the pixels PX and the data drivers DDV. A plurality of data lines may be connected to each of the data drivers DDV.

Although not illustrated, the display device DD may further include a timing controller for controlling operations of the scan driver SDV, the data drivers DDV, and the emission driver EDV. The timing controller may be manufactured in the form of an integrated circuit chip and may be mounted on the printed circuit board PCB. The timing controller may be connected to the data drivers DDV, the scan driver SDV, and the emission driver EDV through the printed circuit board PCB and the flexible circuit boards FPCB.

The scan driver SDV may generate a plurality of scan signals, and the scan signals may be applied to the pixels PX through the scan lines SL1 to SLm. The data drivers DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. The light emission time of the pixels PX may be controlled by the emission signals. The light may be generated by the above-described light emitting elements.

FIG. 6 is a sectional view of one pixel illustrated in FIG. 5.

Referring to FIG. 6, the pixel PX may be disposed on a substrate SUB and may include a transistor TR and a light emitting element OLED. The light emitting element OLED may include a first electrode AE, a second electrode CE, a hole control layer HCL, an electron control layer ECL, and an emissive layer EML. The first electrode AE may be an anode electrode, and the second electrode CE may be a cathode electrode.

The transistor TR and the light emitting element OLED may be disposed on the substrate SUB. Although one transistor TR is illustrated as an example, the pixel PX may substantially include a plurality of transistors and at least one capacitor for driving the light emitting element OLED.

The display area DA may include an emissive area LA corresponding to the pixel PX and a non-emissive area NLA around the emissive area LA. The light emitting element OLED may be disposed in the emissive area LA.

A buffer layer BFL may be disposed on the substrate SUB. The buffer layer BFL may be an inorganic layer. A semiconductor pattern may be disposed on the buffer layer BFL. The semiconductor pattern may include poly silicon. However, without being limited thereto, the semiconductor pattern may include amorphous silicon or metal oxide.

The semiconductor pattern may be doped with an N-type dopant or a P-type dopant. The semiconductor pattern may include highly-doped areas and a lightly-doped area. The highly-doped areas may have a higher conductivity than the lightly-doped area and may substantially serve as a source electrode and a drain electrode of the transistor TR. The lightly-doped area may substantially correspond to an active (or, channel) area of the transistor.

The source S, the active area A, and the drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connecting electrode CNE may be disposed between the transistor TR and the light emitting element OLED and may connect the transistor TR and the light emitting element OLED. The connecting electrode CNE may include a first connecting electrode CNE1 and a second connecting electrode CNE2.

The first connecting electrode CNE1 may be disposed on the third insulating layer INS3 and may be connected to the drain D through a first contact hole CH1 defined in the first to third insulating layers INS1 to INS3. A fourth insulating layer INS4 may be disposed on the first connecting electrode CNE1. A fifth insulating layer INS5 may be disposed on the fourth insulating layer INS4.

The second connecting electrode CNE2 may be disposed on the fifth insulating layer INS5. The second connecting electrode CNE2 may be connected to the first connecting electrode CNE1 through a second contact hole CH2 defined in the fifth insulating layer INS5. A sixth insulating layer INS6 may be disposed on the second connecting electrode CNE2. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole CH3 defined in the sixth insulating layer INS6. A pixel defining layer PDL exposing a certain portion of the first electrode AE may be disposed on the first electrode AE and the sixth insulating layer INS6. A pixel opening PX_OP for exposing the certain portion of the first electrode AE may be defined in the pixel defining layer PDL.

The hole control layer HCL may be disposed on the first electrode AE and the pixel defining layer PDL. The hole control layer HCL may be commonly disposed in the emissive area LA and the non-emissive area NLA. The hole control layer HCL may include a hole transport layer and a hole injection layer.

The emissive layer EML may be disposed on the hole control layer HCL. The emissive layer EML may be disposed in the pixel opening PX_OP. The emissive layer EML may also be disposed around the pixel opening PX_OP. However, substantially, a portion of the emissive layer EML that overlaps the pixel opening PX_OP in a plan view may be defined as the emissive layer EML of the light emitting element OLED. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may be commonly disposed in the emissive area LA and the non-emissive area NLA. The electron control layer ECL may include an electron transport layer and an electron injection layer. The second electrode CE may be disposed on the electron control layer ECL. The second electrode CE may be commonly disposed in the pixels PX.

A thin film encapsulation layer TFE may be disposed on the light emitting element OLED. The thin film encapsulation layer TFE may be disposed on the second electrode CE and may cover the pixel PX. The thin film encapsulation layer TFE may include at least two inorganic layers and an organic layer between the inorganic layers. The inorganic layers may protect the pixel PX from moisture/oxygen. The organic layer may protect the pixel PX from foreign matter such as dust particles.

A first voltage may be applied to the first electrode AE through the transistor TR, and a second voltage having a lower level than the first voltage may be applied to the second electrode CE. Holes and electrons injected into the emissive layer EML may be combined to form excitons, and as the excitons transition to a ground state, the light emitting element OLED may emit light.

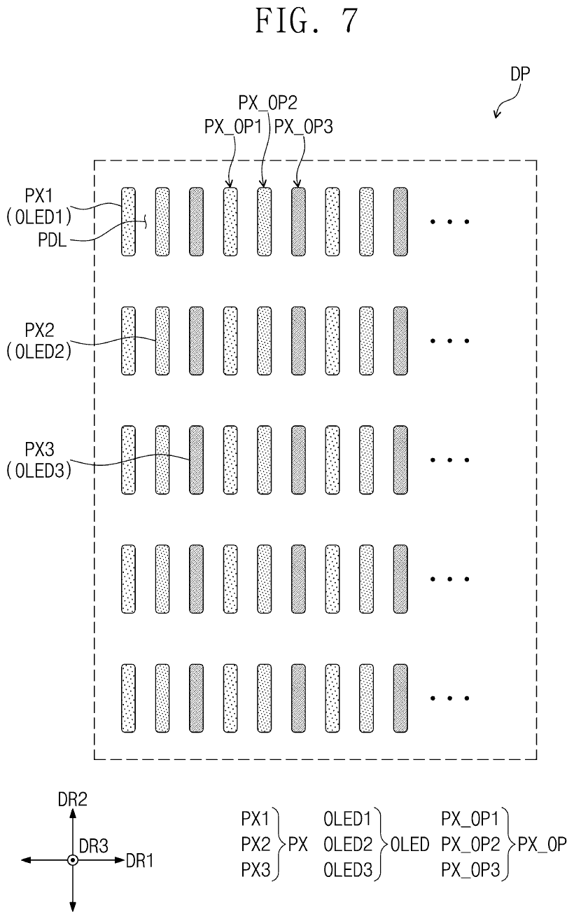

FIG. 7 is a view illustrating light emitting elements disposed in a portion of the display area of the display panel illustrated in FIG. 5.

Referring to FIG. 7, the pixels PX may include a plurality of first pixels PX1, a plurality of second pixels PX2, and a plurality of third pixels PX3. The first pixels PX1 may display red, the second pixels PX2 may display green, and the third pixels PX3 may display blue.

Each of the pixels PX may include the light emitting element OLED illustrated in FIG. 6. The light emitting elements OLED of the pixels PX may include a plurality of first light emitting elements OLED1, a plurality of second light emitting elements OLED2, and a plurality of third light emitting elements OLED3. For example, in FIG. 7, the first light emitting elements OLED1, the second light emitting elements OLED2, and the third light emitting elements OLED3 are illustrated in different gray colors.

The first, second, and third light emitting elements OLED1, OLED2, and OLED3 may be components of the first, second, and third pixels PX1, PX2, and PX3. For example, each of the first pixels PX1 may include the first light emitting element OLED1 that generates red light. Each of the second pixels PX2 may include the second light emitting element OLED2 that generates green light. Each of the third pixels PX3 may include the third light emitting element OLED3 that generates blue light.

The first, second, and third light emitting elements OLED1, OLED2, and OLED3 may be repeatedly arranged in the first direction DR1 in the order of the first light emitting element OLED1, the second light emitting element OLED2, and the third light emitting element OLED3. In addition, the first light emitting elements OLED1 may be arranged in the second direction DR2, the second light emitting elements OLED2 may be arranged in the second direction DR2, and the third light emitting elements OLED3 may be arranged in the second direction DR2.

A plurality of pixel openings PX_OP may be defined in the pixel defining layer PDL. The pixel openings PX_OP may include a plurality of first pixel openings PX_OP1, a plurality of second pixel openings PX_OP2, and a plurality of third pixel openings PX_OP3.

The first light emitting elements OLED1 may be disposed in the first pixel openings PX_OP1. The second light emitting elements OLED2 may be disposed in the second pixel openings PX_OP2. The third light emitting elements OLED3 may be disposed in the third pixel openings PX_OP3.

The first, second, and third pixel openings PX_OP1, PX_OP2, and PX_OP3 may be repeatedly arranged in the first direction DR1 in the order of the first pixel opening PX_OP1, the second pixel opening PX_OP2, and the third pixel opening PX_OP3. In addition, the first pixel openings PX_OP1 may be arranged in the second direction DR2, the second pixel openings PX_OP2 may be arranged in the second direction DR2, and the third pixel openings PX_OP3 may be arranged in the second direction DR2.

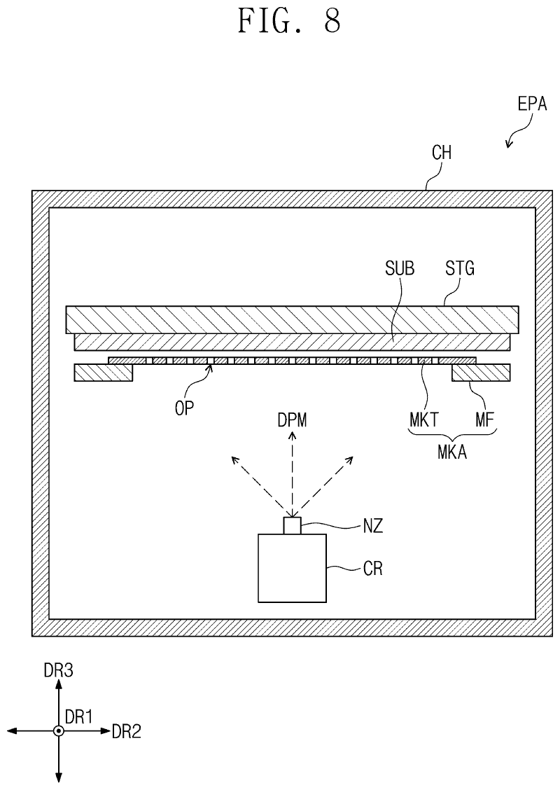

FIG. 8 is a sectional view illustrating a deposition device including the mask assembly illustrated in FIGS. 1 to 3.

For example, in FIG. 8, a cross-section of the mask assembly MKA viewed in the first direction DR1 is illustrated.

Referring to FIG. 8, the deposition device EPA may include a chamber CH, a stage STG, the mask assembly MKA, a crucible CR, and a nozzle NZ. The chamber CH may be defined as a vacuum chamber. The stage STG, the mask assembly MKA, the crucible CR, and the nozzle NZ may be disposed in the chamber CH.

The substrate SUB may be disposed on the lower surface of the stage STG. Although not illustrated, the stage STG may include vacuum holes for clamping the substrate SUB by vacuum pressure. In addition, without being limited thereto, a support part for supporting opposite sides of the substrate SUB may be used instead of the stage STG. The substrate SUB may be disposed such that the pixel opening PX_OP illustrated in FIG. 6 faces downward.

The mask assembly MKA may be disposed under the substrate SUB. The mask assembly MKA may be disposed adjacent to the substrate SUB. The mask stick MKT may be disposed on the mask frame MF, and the substrate SUB may be disposed over the mask stick MKT. The mask stick MKT may be disposed adjacent to the substrate SUB.

The crucible CR may be disposed under the mask assembly MKA. Accordingly, the mask assembly MKA may be disposed between the stage STG and the crucible CR. Although not illustrated, a deposition material DPM may be accommodated in the crucible CR, and a heating wire for heating the deposition material DPM may be disposed in the crucible CR.

The nozzle NZ may be disposed on the crucible CR. The nozzle NZ may be connected to the crucible CR. The nozzle NZ may be disposed to face toward the mask assembly MKA.

The deposition material DPM heated in the crucible CR may be vaporized, and the vaporized deposition material DPM may be dispensed through the nozzle NZ. The deposition material DPM may be provided on the substrate SUB through the frame opening F-OP and the openings OP defined in the mask stick MKT.

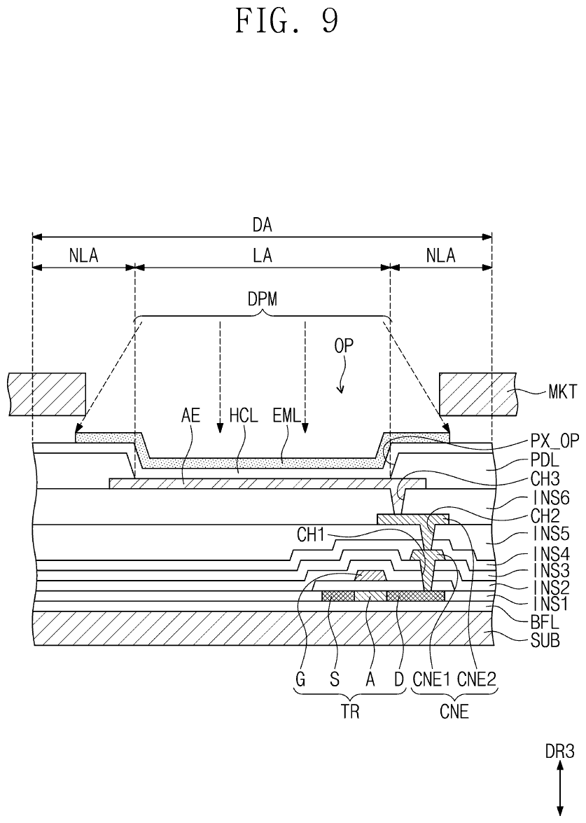

FIG. 9 is a sectional view for explaining a process of forming an emissive layer using the deposition device illustrated in FIG. 8.

Referring to FIG. 9, the mask stick MKT may be disposed over the substrate SUB. For convenience of description, the pixel defining layer PDL is illustrated as facing upward, and the mask stick MKT is illustrated as being disposed over the pixel defining layer PDL. However, the structure illustrated in FIG. 9 may substantially correspond to an inverted state of FIG. 8 in a deposition process. For example, in FIG. 8, the pixel defining layer PDL may face downward, and the mask stick MKT may be disposed under the pixel defining layer PDL.

The hole control layer HCL may be disposed on the first electrode AE, and the mask stick MKT may be used to form the emissive layer EML on the hole control layer HCL. The deposition material DPM may be provided on the hole control layer HCL through the opening OP defined in the mask stick MKT. The emissive layer EML may be formed by the deposition material DPM.

Although one emissive layer EML is formed on the substrate SUB, a plurality of emissive layers EML may be substantially formed on the substrate SUB.

When viewed from above the plane, the area of the opening OP may be greater than the area of the pixel opening PX_OP. The deposition material DPM may be provided on the substrate SUB to have an area corresponding to the opening OP. Since the area of the opening OP is greater than the area of the pixel opening PX_OP, the deposition material DPM may be provided to the pixel opening PX_OP and around the pixel opening PX_OP.

It may be difficult to precisely provide the deposition material only to the pixel opening PX_OP. Therefore, in consideration of a process margin, the area of the opening OP may be formed to be greater than the area of the pixel opening PX_OP. Even though the emissive layer EML is also provided around the pixel opening PX_OP, the portion of the emissive layer EML that overlaps the pixel opening PX_OP in a plan view may be driven by the portion of the first electrode AE exposed by the pixel opening PX_OP.

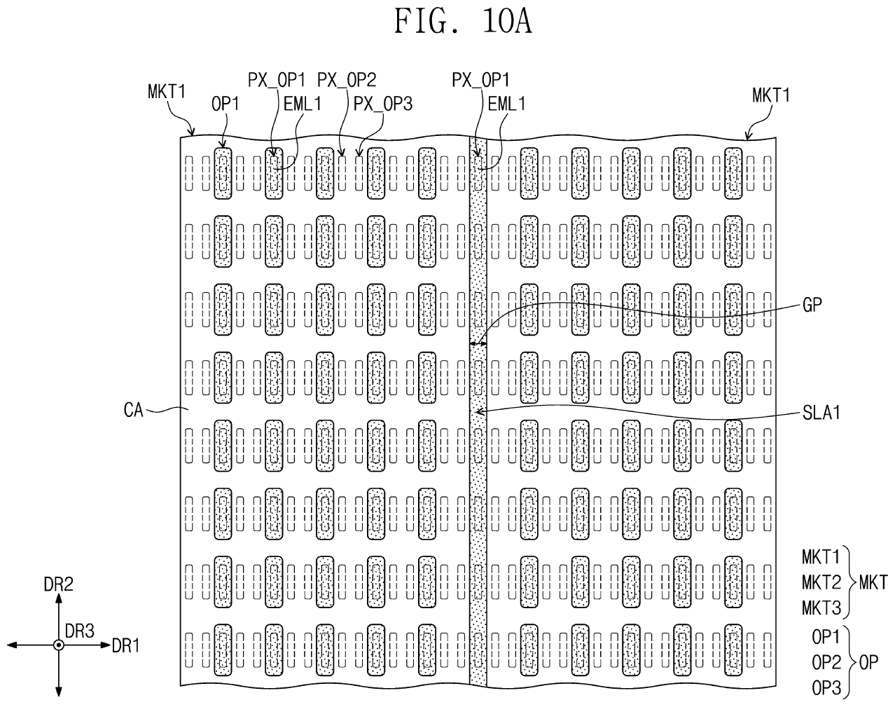

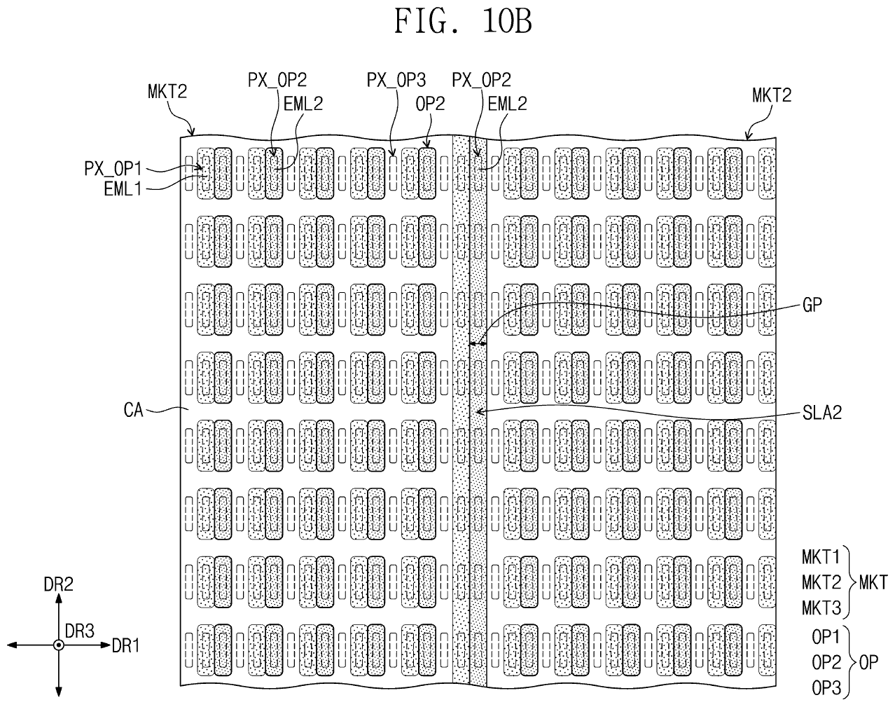

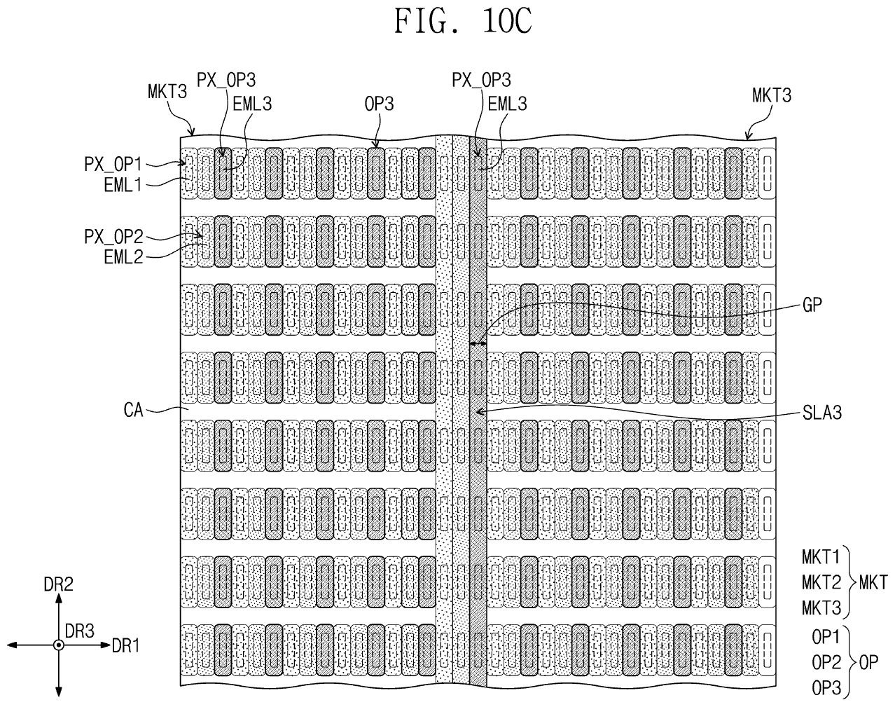

FIGS. 10A, 10B, and 10C are plan views for explaining a process of forming first, second, and third light emitting elements through mask sticks.

For example, in FIGS. 10A, 10B, and 10C, the first, second, and third pixel openings PX_OP1, PX_OP2, and PX_OP3 defined on the substrate SUB are illustrated together with the openings OP of the mask sticks MKT. For example, in FIGS. 10A, 10B, and 10C, the peripheries of the first, second, and third pixel openings PX_OP1, PX_OP2, and PX_OP3 are illustrated by dotted lines.

For example, two mask sticks MKT adjacent to each other in the first direction DR1 are illustrated, and the masks MKT may substantially correspond to the plan view of the mask sticks MKT illustrated in FIG. 4.

For example, in FIGS. 10A, 10B, and 10C, the first, second, and third pixel openings PX_OP1, PX_OP2, and PX_OP3 on the left outer side of the left mask stick MKT and the right outer side of the right mask stick MKT are omitted.

Referring to FIGS. 10A, 10B, and 10C, the mask sticks MKT may include a plurality of first mask sticks MKT1, a plurality of second mask sticks MKT2, and a plurality of third mask sticks MKT3. When the process of forming the first, second, and third light emitting elements OLED1, OLED2, and OLED3 is performed, the first mask sticks MKT1 may be used firstly, the second mask sticks MKT2 may be used secondly, and the third mask sticks MKT3 may be used thirdly.

Although not illustrated, the mask frame MF may include a first mask frame, a second mask frame, and a third mask frame. The first mask sticks MKT1 may be used in combination with the first mask frame, the second mask sticks MKT2 may be used in combination with the second mask frame, and the third mask sticks MKT3 may be used in combination with the third mask frame.

First openings OP1 may be defined in the first mask sticks MKT1. Second openings OP2 may be defined in the second mask sticks MKT2. Third openings OP3 may be defined in the third mask sticks MKT3. Accordingly, the openings OP of the mask sticks MKT may include the first openings OP1, the second openings OP2, and the third openings OP3.

Hereinafter, an emissive layer of each of the first light emitting elements OLED1 is defined as a first emissive layer EML1, an emissive layer of each of the second light emitting elements OLED2 is defined as a second emissive layer EML2, and an emissive layer of each of the third light emitting elements OLED3 is defined as a third emissive layer EML3.

Referring to FIG. 10A, the first mask sticks MKT1 may be disposed over the substrate SUB. The first mask sticks MKT1 may be spaced apart from each other by the predetermined gap GP in the first direction DR1, and the space between the first mask sticks MKT1 may be defined as a first slit area SLA1. The first slit area SLA1 may extend in the second direction DR2.

Substantially, the number of first mask sticks MKT1 may be more than two as illustrated in FIGS. 1 to 3. In this case, a plurality of first slit areas SLA1 may be defined between the first mask sticks MKT1.

The first slit area SLA1 between the h^{th} first mask stick MKT1 and the (h+1)^{th} first mask stick MKT1 may overlap the first pixel openings PX_OP1 arranged in one corresponding column among the first pixel openings PX_OP1 arranged in the plurality of columns. “h” may be a natural number, and the columns may correspond to the second direction DR2. The first openings OP1 of each of the h^{th} first mask stick MKT1 and the (h+1)^{th} first mask stick MKT1 may overlap the corresponding first pixel openings PX_OP1 in a plan view, respectively.

The above-described deposition material DPM may be provided on the substrate SUB through the first openings OP1 and the first slit area SLA1. The deposition material DPM may include a first deposition material for forming the first emissive layers EML1. The first deposition material may be provided to the first pixel openings PX_OP1 through the first openings OP1 and the first slit area SLA1.

Depending on the deposition process, the first emissive layers EML1 of a dot type may be formed on the substrate SUB that overlaps the first mask sticks MKT1 in a plan view. The first emissive layers EML1 may be formed in a stripe shape extending in the second direction DR2 on the substrate SUB overlapping the first slit area SLA1 in a plan view.

Referring to FIG. 10B, the second mask sticks MKT2 may be disposed over the substrate SUB after the first mask sticks MKT1 are removed. The second mask sticks MKT2 may be spaced apart from each other by the predetermined gap GP in the first direction DR1, and the space between the second mask sticks MKT2 may be defined as a second slit area SLA2. The second slit area SLA2 may extend in the second direction DR2.

Substantially, the number of second mask sticks MKT2 may be more than two as illustrated in FIGS. 1 to 3. In this case, a plurality of second slit areas SLA2 may be defined between the second mask sticks MKT2.

The second slit area SLA2 between the h^{th} second mask stick MKT2 and the (h+1)^{th} second mask stick MKT2 may overlap the second pixel openings PX_OP2 arranged in one corresponding column among the second pixel openings PX_OP2 arranged in the plurality of columns. The second openings OP2 of each of the h^{th} second mask stick MKT2 and the (h+1)^{th} second mask stick MKT2 may overlap the corresponding second pixel openings PX_OP2 in a plan view, respectively.

The above-described deposition material DPM may be provided on the substrate SUB through the second openings OP2 and the second slit area SLA2. The deposition material DPM may include a second deposition material for forming the second emissive layers EML2. The second deposition material may be provided to the second pixel openings PX_OP2 through the second openings OP2 and the second slit area SLA2.

Depending on the deposition process, the second emissive layers EML2 of a dot type may be formed on the substrate SUB that overlaps the second mask sticks MKT2 in a plan view. The second emissive layers EML2 may be formed in a stripe shape extending in the second direction DR2 on the substrate SUB overlapping the second slit area SLA2 in a plan view.

For example, in FIG. 10B, the second openings OP2 are illustrated by thick lines, and the portions to which the first deposition material is provided are illustrated by thin lines.

Referring to FIG. 10C, the third mask sticks MKT3 may be disposed over the substrate SUB after the second mask sticks MKT2 are removed. The third mask sticks MKT3 may be spaced apart from each other by the predetermined gap GP in the first direction DR1, and the space between the third mask sticks MKT3 may be defined as a third slit area SLA3. The third slit area SLA3 may extend in the second direction DR2.

Substantially, the number of third mask sticks MKT3 may be more than two as illustrated in FIGS. 1 to 3. In this case, a plurality of third slit areas SLA3 may be defined between the third mask sticks MKT3.

The third slit area SLA3 between the h^{th} third mask stick MKT3 and the (h+1)^{th} third mask stick MKT3 may overlap the third pixel openings PX_OP3 arranged in one corresponding column among the third pixel openings PX_OP3 arranged in the plurality of columns. The third openings OP3 of each of the h^{th} third mask stick MKT3 and the (h+1)^{th} third mask stick MKT3 may overlap the corresponding third pixel openings PX_OP3 in a plan view, respectively.

The above-described deposition material DPM may be provided on the substrate SUB through the third openings OP3 and the third slit area SLA3. The deposition material DPM may include a third deposition material for forming the third emissive layers EML3. The third deposition material may be provided to the third pixel openings PX_OP3 through the third openings OP3 and the third slit area SLA3.

The first, second, and third deposition materials described above may be accommodated in separate crucibles, respectively, and may be provided on the substrate SUB.

Depending on the deposition process, the third emissive layers EML3 of a dot type may be formed on the substrate SUB that overlaps the third mask sticks MKT3 in a plan view. The third emissive layers EML3 may be formed in a stripe shape extending in the second direction DR2 on the substrate SUB overlapping the third slit area SLA3 in a plan view.

For example, in FIG. 10C, the third openings OP3 are illustrated by thick lines, and the portions to which the first deposition material and the second deposition material are provided are illustrated by thin lines. In addition, the portions to which the first deposition material is provided, the portions to which the second deposition material is provided, and the portions to which the third deposition material is provided are illustrated in different gray colors.

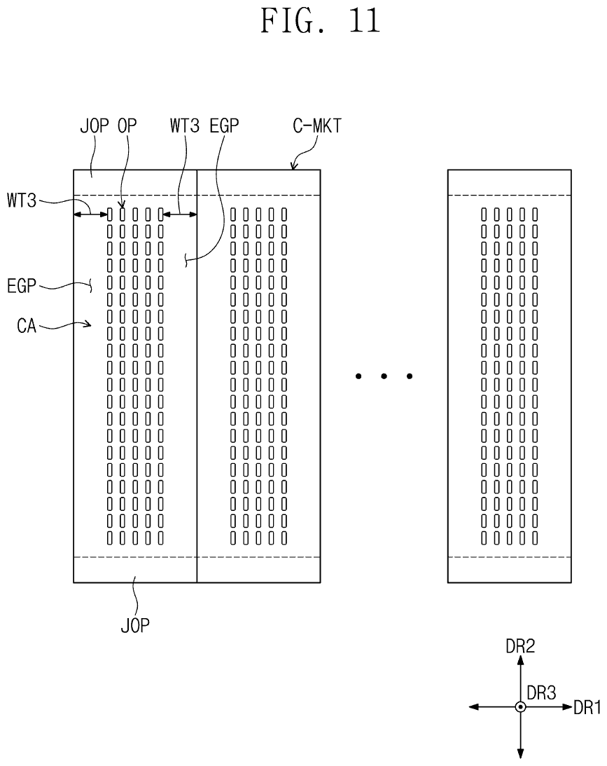

FIG. 11 is a view illustrating a configuration of mask sticks according to a comparative example.

Referring to FIG. 11, unlike the above-described mask sticks MKT, edge portions EGP of each of the mask sticks C-MKT according to the comparative example may have a third width WT3 in the first direction DR1. The third width WT3 may be greater than the first width WT1 and the second width WT2 described above. That is, the widths of the edge portions EGP of the mask sticks C-MKT according to the comparative example may be greater than the widths of the first edge portions EGP1 and the second edge portions EGP2 of the mask sticks MKT.

The display panel DP illustrated in FIG. 5 may be defined as a large panel with a high resolution. When the mask sticks C-MKT according to the comparative example are used to manufacture the display panel DP, a deposition process of emissive layers EML of some light emitting elements OLED overlapping the edge portions EGP having a relatively large width may not be performed.

In an embodiment of the present disclosure, since the widths of the first edge portions EGP1 and the second edge portions EGP2 of the mask sticks MKT are reduced, the emissive layers EML of the light emitting elements OLED of the display panel DP may be more easily formed as a large panel with a high resolution.

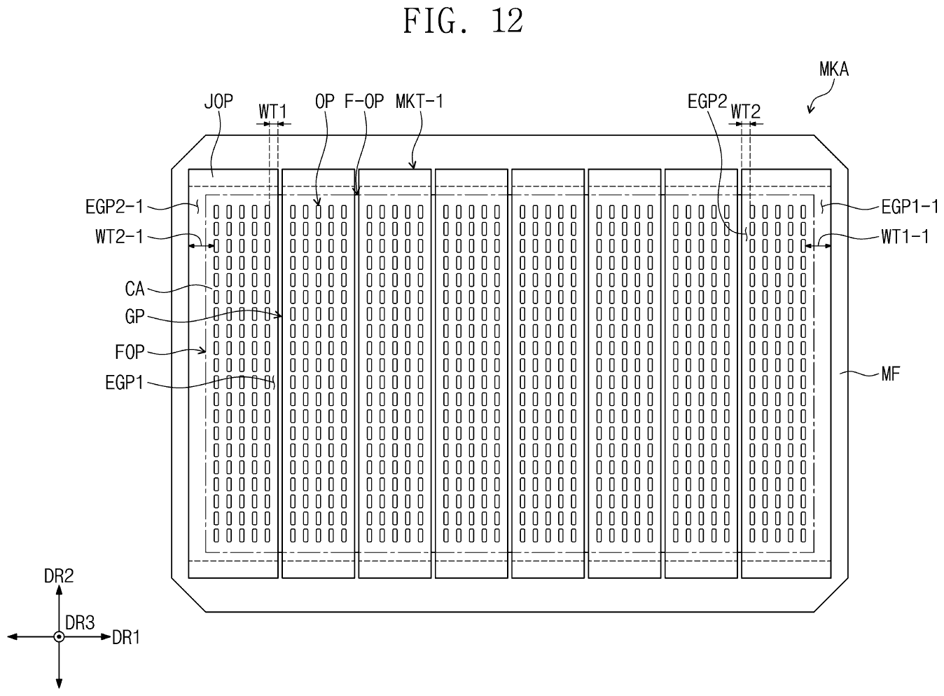

FIG. 12 is a plan view illustrating a configuration of mask sticks according to an embodiment of the present disclosure.

For example, FIG. 12 is a plan view corresponding to FIG. 3. Hereinafter, components of the mask sticks MKT-1 illustrated in FIG. 12 will be described focusing on components different from those of the mask sticks MKT illustrated in FIG. 3.

For example, in FIG. 12, a frame opening F-OP overlapping the mask sticks MKT-1 in a plan view is illustrated by a dash-dot-dash line.

Referring to FIG. 12, the mask sticks MKT-1 disposed on the leftmost side and the rightmost side may not have bilateral symmetry. For example, a first edge portion EGP1 of the leftmost mask stick MKT-1 may have a first width WT1 in the first direction DR1, and a second edge portion EGP2-1 of the leftmost mask stick MKT-1 may have a second width WT2-1 in the first direction DR1. The second width WT2-1 may be greater than the first width WT1. The second edge portion EGP2-1 may be coupled to a mask frame MF to overlap the mask frame MF in a plan view.

A first edge portion EGP1-1 of the rightmost mask stick MKT-1 may have a first width WT1-1 in the first direction DR1, and a second edge portion EGP2 of the rightmost mask stick MKT-1 may have a second width WT2 in the first direction DR1. The first width WT1-1 may be greater than the second width WT2. The first edge portion EGP1-1 may be coupled to the mask frame MF to overlap the mask frame MF in a plan view.

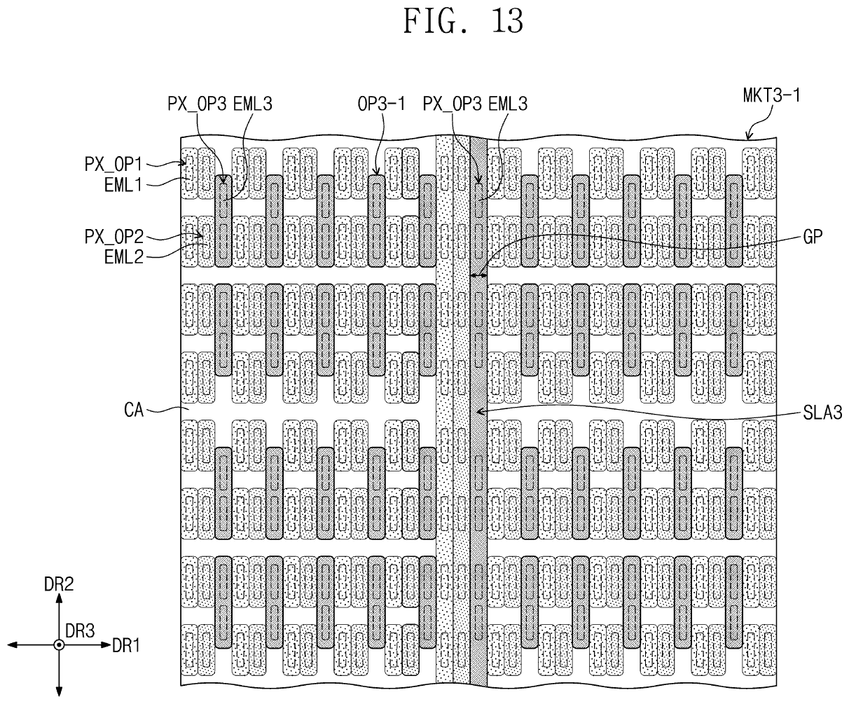

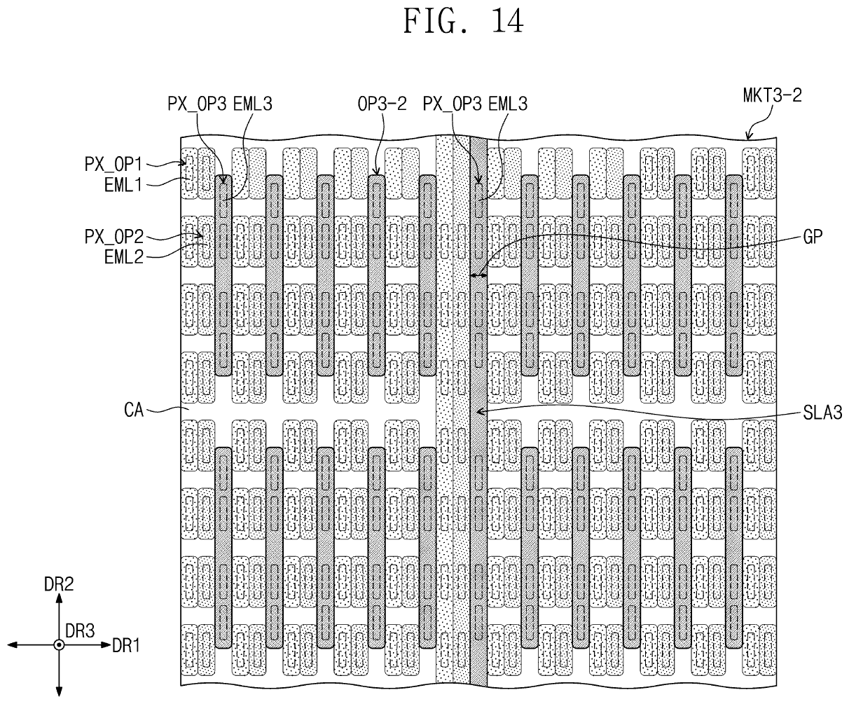

FIGS. 13 and 14 are plan views illustrating a configuration of third mask sticks according to embodiments of the present disclosure.

For example, FIGS. 13 and 14 are plan views corresponding to FIG. 10C. Hereinafter, components of the third mask sticks MKT3-1 and MKT3-2 illustrated in FIGS. 13 and 14 will be described focusing on components different from those of the third mask sticks MKT3 illustrated in FIG. 10C.

Referring to FIG. 13, third pixel openings PX_OP3 disposed in the same column may be provided in pairs in the second direction DR2 so as to be adjacent to each other. Each of third openings OP3-1 of the third mask sticks MKT3-1 may overlap two third pixel openings PX_OP3 adjacent to each other among the third pixel openings PX_OP3 in a plan view. In this case, two third emissive layers EML3 adjacent to each other in the second direction DR2 may be formed by one third opening OP3-1.

Referring to FIG. 14, third pixel openings PX_OP3 disposed in the same column may be provided in pairs in the second direction DR2 so as to be adjacent to each other. In addition, two pairs of third pixel openings PX_OP3 may be adjacent to each other.

Each of third openings OP3-2 of the third mask sticks MKT3-2 may overlap two pairs of third pixel openings PX_OP3 adjacent to each other among the third pixel openings PX_OP3 in a plan view. In this case, four third emissive layers EML3 adjacent to each other in the second direction DR2 may be formed by one third opening OP3-2.

Although two or four third pixel openings PX_OP3 are adjacent to each other, the present disclosure is not limited thereto, and six third pixel openings PX_OP3 may be adjacent to each other and may overlap one third opening OP3 in a plan view.

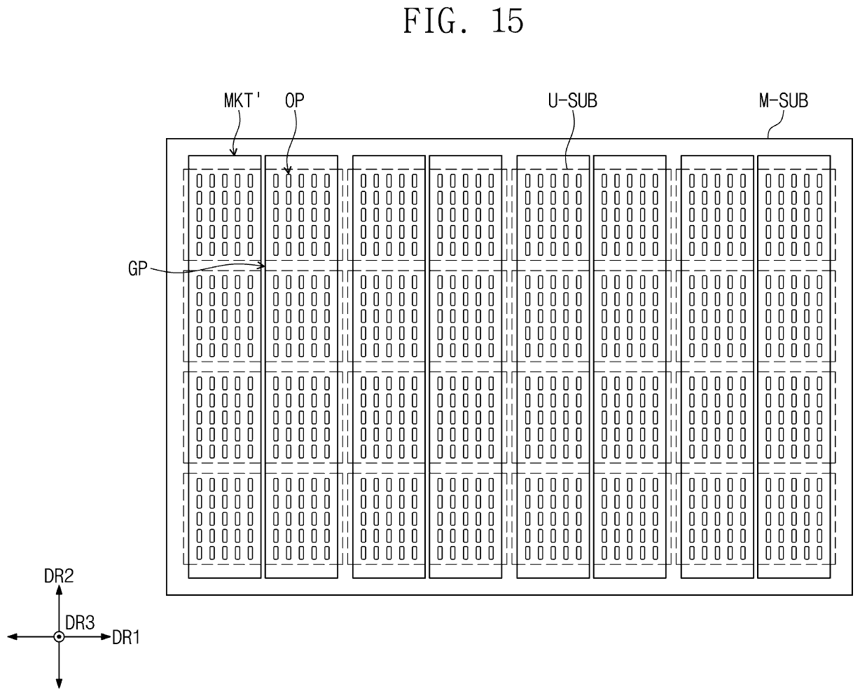

FIG. 15 is a plan view illustrating an example in which a mask assembly according to an embodiment of the present disclosure is used for a small or medium-sized display panel.

For example, in FIG. 15, a mask frame MF is omitted, and a mother substrate M-SUB is illustrated together with mask sticks MKT′.

Referring to FIG. 15, the mother substrate M-SUB including a plurality of unit substrates U-SUB may be prepared. The unit substrates U-SUB may be arranged in the first direction DR1 and the second direction DR2. For example, unit substrates U-SUB arranged in four rows and four columns are illustrated. However, the number of unit substrates U-SUB is not limited thereto. The rows may correspond to the first direction DR1, and the columns may correspond to the second direction DR2.

Each of the unit substrates U-SUB may extend longer in the first direction DR1 than in the second direction DR2. That is, the unit substrate U-SUB may have a rectangular shape with short sides extending in the second direction DR2 and long sides extending in the first direction DR1.

The mother substrate M-SUB may be disposed on the mask sticks MKT′. Among the mask sticks MKT′, at least two mask sticks MKT′ adjacent to each other in the first direction DR1 may be disposed to overlap the unit substrates U-SUB arranged in one column in a plan view.

The mask sticks MKT′ may have substantially the same configuration as the mask sticks MKT illustrated in FIG. 5. However, openings OP of the mask sticks MKT′ may be defined to overlap the unit substrates U-SUB in a plan view and may not be defined between the unit substrates U-SUB in the second direction DR2.

The above-described pixel openings PX_OP may be defined in each of the unit substrates U-SUB. Accordingly, emissive layers EML may be formed on the unit substrates U-SUB by the mask sticks MKT′.

When pixels are formed on the unit substrates U-SUB, the unit substrates U-SUB may be separated from the mother substrate M-SUB and may be used as display panels. The display panels may be defined as small and medium-sized panels. In an embodiment of the present disclosure, the mask sticks MKT′ may be used to manufacture the small and medium-sized panels.

According to the embodiments of the present disclosure, the widths of the edge portions of the mask sticks may be reduced, and thus light emitting elements of a high-resolution display panel may be more easily manufactured.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A deposition device for manufacturing a display device comprising:
a mask frame in which a frame opening is defined; and
a mask stick disposed on the mask frame and extending longer in a second direction than extending in a first direction crossing the second direction,
wherein a plurality of openings arranged in the first direction and the second direction are defined in the mask stick,
wherein the mask stick includes:
first branch portions between openings adjacent to each other in the first direction among the plurality of openings; and
a first edge portion between a first side of opposite sides of the mask stick opposite each other in the first direction and openings adjacent to the first side among the plurality of openings, and
wherein in the first direction, a first width of the first edge portion is set in a range of 90% of a first branch width of each of the first branch portions to 110% of the first branch width.

2. The deposition device of claim 1, wherein the first width is equal to the first branch width.

3. The deposition device of claim 1, wherein the mask stick further includes:
second branch portions between openings adjacent to each other in the second direction among the plurality of openings; and
a second edge portion between a second side of the opposite sides of the mask stick and openings adjacent to the second side among the plurality of openings.

4. The deposition device of claim 3, wherein a second branch width of each of the second branch portions in the second direction is smaller than the first branch width.

5. The deposition device of claim 3, wherein in the first direction, a second width of the second edge portion is equal to the first width.

6. The deposition device of claim 5, wherein the second width is equal to the first branch width.

7. The deposition device of claim 3, wherein in the first direction, a second width of the second edge portion is greater than the first width.

8. The deposition device of claim 1, wherein the first width is set to 300 micrometers or less.

9. The deposition device of claim 1, wherein the mask stick is provided in plural, and the plurality of mask sticks are arranged in the first direction.

10. The deposition device of claim 9, wherein two adjacent mask sticks among the plurality of mask sticks are spaced apart from each other by a predetermined gap in the first direction.

11. The deposition device of claim 9, wherein a gap between two mask sticks adjacent to each other in the first direction among the plurality of mask sticks is equal to a width of each of the plurality of openings in the first direction.

12. The deposition device of claim 9, wherein the deposition device is configured so that a substrate is disposed over the mask sticks,
wherein a plurality of first pixel openings in which a plurality of first light emitting elements are disposed, a plurality of second pixel openings in which a plurality of second light emitting elements are disposed, and a plurality of third pixel openings in which a plurality of third light emitting elements are disposed are defined in a pixel defining layer disposed on the substrate to face toward the mask sticks,
wherein the first pixel openings, the second pixel openings, and the third pixel openings are repeatedly arranged in the first direction in an order of a first pixel opening, a second pixel opening, and a third pixel opening, and
wherein the first pixel openings are arranged in the second direction, the second pixel openings are arranged in the second direction, and the third pixel openings are arranged in the second direction.

13. The deposition device of claim 12, wherein the mask sticks include:
a plurality of first mask sticks in which a plurality of first openings are defined;
a plurality of second mask sticks in which a plurality of second openings are defined; and
a plurality of third mask sticks in which a plurality of third openings are defined,
wherein a first slit area between an h^{th} first mask stick and an (h+1)^{th} first mask stick overlaps first pixel openings arranged in one column among the plurality of first pixel openings, h is a natural number, and the column extends in the second direction, and
wherein first openings defined in the h^{th} first mask stick and the (h+1)^{th} first mask stick among the plurality of first openings overlap corresponding first pixel openings, respectively.

14. The deposition device of claim 13, wherein a second slit area between an h^{th} second mask stick and an (h+1)^{th} second mask stick overlaps second pixel openings arranged in one column extending in the second direction among the plurality of second pixel openings, and
wherein second openings defined in the h^{th} second mask stick and the (h+1)^{th} second mask stick among the plurality of second openings overlap corresponding second pixel openings, respectively.

15. The deposition device of claim 13, wherein a third slit area between an h^{th} third mask stick and an (h+1)^{th} third mask stick overlaps third pixel openings arranged in one column extending in the second direction among the plurality of third pixel openings, and
wherein third openings defined in the h^{th} third mask stick and the (h+1)^{th} third mask stick among the plurality of third openings overlap corresponding third pixel openings, respectively.

16. The deposition device of claim 13, wherein each of the plurality of third openings overlaps at least two third pixel openings arranged in the second direction among the plurality of third openings.

17. The deposition device of claim 9, wherein a mother substrate including a plurality of unit substrates is disposed on the mask sticks,
wherein each of the unit substrates extend longer in the first direction than extend in the second direction, and
wherein at least two mask sticks among the plurality of mask sticks overlap unit substrates arranged in one column extended along the second direction among the plurality of unit substrates.

18. A mask assembly for manufacturing a display device comprising:
a mask frame in which a frame opening is defined; and
a mask stick disposed on the mask frame and extending longer in a second direction than extending in a first direction crossing the second direction,
wherein a plurality of openings arranged in the first direction and the second direction are defined in the mask stick,
wherein the mask stick includes:
first branch portions between openings adjacent to each other in the first direction among the plurality of openings;
a first edge portion between a first side of opposite sides of the mask stick opposite each other in the first direction and openings adjacent to the first side among the plurality of openings, and
a second edge portion between a second side of the opposite sides of the mask stick and openings adjacent to the second side among the plurality of openings, and
wherein in the first direction, a first width of the first edge portion and a second width of the second edge portion are each set in a range of 90% of a first branch width of each of the first branch portions to 110% of the first branch width.

19. The mask assembly of claim 18, wherein each of the first width and the second width is equal to the first branch width.

20. A mask assembly for manufacturing a display device comprising:
a mask frame in which a frame opening is defined; and
a plurality of mask sticks disposed on the mask frame and arranged in a first direction,
wherein each of the mask sticks extends longer in a second direction than extends in a first direction crossing the second direction,
wherein a plurality of openings arranged in the first direction and the second direction are defined in each of the plurality of mask sticks,
wherein each of the plurality of mask sticks includes:
first branch portions between openings adjacent to each other in the first direction among the plurality of openings; and
a first edge portion between a first side of opposite sides of each of the mask stick opposite each other in the first direction and openings adjacent to the first side among the plurality of openings,
wherein in the first direction, a first width of the first edge portion is set in a range of 90% of a first branch width of each of the first branch portions to 110% of the first branch width, and
wherein a gap between two mask sticks adjacent to each other in the first direction among the plurality of mask sticks is equal to a width of each of the plurality of openings in the first direction.
